(19) United States
(12) Patent Application Publication
(10) Pub. No.: US 2025/0342896 A1
(43) Pub. Date: Nov. 6, 2025

(54) CURRENT-CONTROLLED ANALOG MEMORY CIRCUITS BUILT FROM NON-VOLATILE MEMORY ELEMENTS

(71) Applicant: University of Tennessee Research Foundation, Knoxville, TN (US)

(72) Inventors: Garrett Steven Rose, Knoxville, TN (US); Ryan J. Weiss, Knoxville, TN (US)

(73) Assignee: University of Tennessee Research Foundation, Knoxville, TN (US)

(21) Appl. No.: 18/973,648

(22) PCT Filed: Jun. 8, 2023
(86) PCT No.: PCT/US2023/024807

§ 371 Date: Dec. 9, 2024

Related U.S. Application Data
(60) Provisional application No. 63/350,250, filed on Jun. 8, 2022.

(51) Int. Cl. G11C 27/00

(52) U.S. Cl. CPC G11C 27/005

(57) ABSTRACT

In some examples, a method for controlling an analog memory cell using a non-volatile memory (NVM) element includes applying an analog voltage to a gate of a select transistor. The method includes providing, by the select transistor, a substantially constant current through the NVM element. The method includes causing the NVM element to transition from a high resistance state (HRS) to a low resistance state (LRS), causing a voltage drop across the NVM device and resulting resistance drop toward a target LRS resistance level directly proportional to the analog voltage applied to the gate of the select transistor.

### PRIORITY CLAIM

This application claims the benefit of U.S. Provisional Patent Application Ser. No. 63/350,250 filed Jun. 8, 2022, the disclosure of which is incorporated herein by reference in its entirety.

### GRANT STATEMENT

This invention was made with government support under Contract Number FA8750-19-1-0025 awarded by the Air Force Research Laboratory. The government has certain rights in the invention.

### BACKGROUND

In computing, memory is a device or system that is used to store information for immediate use in a computer or related computer hardware and digital electronic devices. Computer memory typically operates at a high speed compared to storage that is slower but less expensive and higher in capacity. Besides storing opened programs, computer memory serves as disk cache and write buffer to improve both reading and writing performance.

Conventional memory can be implemented as semiconductor memory, where data is stored within memory cells built from MOS transistors and other components on an integrated circuit. There are two main kinds of semiconductor memory, volatile and non-volatile. Examples of non-volatile memory are flash memory and ROM, PROM, EPROM and EEPROM memory. Examples of volatile memory are dynamic random-access memory (DRAM) used for primary storage, and static random-access memory (SRAM) used for CPU cache.

### SUMMARY

In some examples, a method for controlling an analog memory cell using a non-volatile memory (NVM) element includes applying an analog voltage to a gate of a select transistor. The method includes providing, by the select transistor, a substantially constant current through the NVM element. The method includes causing the NVM element to transition from a high resistance state (HRS) to a low resistance state (LRS), causing a voltage drop across the NVM device and resulting resistance drop toward a target LRS resistance level directly proportional to the analog voltage applied to the gate of the select transistor.

In some examples, current-controlled analog memory circuit includes a non-volatile memory (NVM) element. The circuit includes a select transistor coupled to the NVM element and configured to store an analog value as a resistance of the NVM element by providing a substantially constant current through the NVM element and causing the NVM element to transition from a high resistance state (HRS) to a low resistance state (LRS), causing a voltage drop across the NVM device and resulting resistance drop toward a target LRS resistance level directly proportional to an analog voltage applied to a gate of the select transistor.

In some examples, a system for spike-timing-dependent plasticity (STDP) online learning includes a current-controlled memristive synapse. The system includes an STDP online learning circuit configured for limiting a range of operation of the current-controlled memristive synapse to resistance states near the low resistance state (LRS) of the current-controlled memristive synapse.

Accordingly, it is an object of the presently disclosed subject matter to provide analog memory cells using a non-volatile memory (NVM) element. This and other objects are achieved in whole or in part by the presently disclosed subject matter. Further, an object of the presently disclosed subject matter having been stated above, other objects and advantages of the presently disclosed subject matter will become apparent to those skilled in the art after a study of the following description, Figures, and Examples.

### BRIEF DESCRIPTION OF DRAWINGS

FIG. 1 is a schematic of the current-controlled analog memory circuit, with a two-terminal NVM element (M_{R}) used to store an analog value as the resistance of the device.

FIG. 2 is a graph showing, for an example system, results for the current through both transistor and NVM element as a function of the applied gate voltage (Cmp in FIG. 1). This illustrates how current is controlled by Cmp.

FIG. 3 is chart showing the maximum achievable voltage range, for smallest M_{R} resistance minus that of the largest, for different values of Cmp in parentheses during a read operation. Shown for different widths for M_{P3}.

FIG. 4 is a graph showing the expected output current for different resistances relative to 3 kΩ using a 500 nm M_{P3} at Cmp 600 mV.

FIGS. 5A-5B illustrate an example STDP circuit.

FIG. 6 is diagram of an example current controlled memristive analog memory circuit.

FIGS. 7A-7D illustrate potential transistor-level circuit implementations.

FIG. 8 is a depression timing waveform diagram.

FIG. 9 is a potentiation timing waveform diagram.

FIG. 10 is an STDP curve for change in resistance relative to spike timing.

FIG. 11 is a flow diagram of an example method for controlling an analog memory cell using an NVM element.

### DETAILED DESCRIPTION

This document describes a reliable current-controlled mechanism for writing and reading analog memory cells built from two-terminal non-volatile memory (NVM) elements. An example use case of the analog memory cell is to provide very dense storage of continuous synaptic weights in a brain-inspired computer system, such as a machine learning accelerator or neuromorphic compute engine. The current-controlled mechanism itself refers to the control of a constant current that dictates how the NVM element switches from a high resistance state (HRS) to a specific low resistance state (LRS). An analog voltage is provided to the gate of a select transistor which in turn provides the constant current through the NVM element. As the NVM element starts in HRS, the voltage drop across the NVM device, courtesy Ohm's Law, is large enough that the device will begin to switch, meaning the resistance is reduced according to the applied voltage. Since this voltage is determined by a constant current, the voltage drop is also reduced as the resistance of the NVM device is reduced toward a specific desired LRS resistance level. Once the voltage is small enough that it no longer exceeds the switching threshold of the NVM element, the switching process stops at the desired resistance value. This analog resistance value is directly proportional to the analog value being stored in the analog memory circuit.

Reading the analog memory cell also depends on supplying a constant current using the control transistor. However, to read out the analog value, a small current is supplied such that the voltage drop across the NVM device never exceeds the switching threshold. Instead, the voltage between the select transistor and the NVM element is predominantly dependent on the resistance of the NVM element itself, as the transistor drain-to-source voltage is effectively constant during read out. Thus, this analog voltage at the node between NVM element and transistor is representative of the analog value being stored. For read out, an optional second stage is suggested that can convert the read out voltage to a current value that is also directly proportional to the analog LRS resistance value being stored on the NVM element. A current representation is useful for further analog computations, including the summation of weighted inputs that is critically important to machine learning operations.

Some examples of NVM elements include: metal-oxide memristors (memory resistors), phase change memory (PCM) devices, and magnetic tunnel junction (MTJ) elements. Any such NVM element could be used in the construction of a current-controlled analog memory circuit. However, the operation of the provided example was explored specifically for memristor circuit elements whose resistance changes as a function of the integral of applied voltage over time. For a bipolar memristor, if this applied voltage is greater than the positive threshold, then the resistance will be reduced proportional to the voltage magnitude and time of application. Likewise, a negative applied voltage that is less than a negative threshold will result in an increase in the resistance value at a rate proportional to the voltage magnitude and time of application. Smaller applied voltages, of magnitude less than either threshold value, result in no or negligible change in the analog resistance value. Importantly, if no voltage is applied, the NVM element will remain in the last analog resistance state. Hence, the device is considered non-volatile as its resistance does not change for small or zero applied voltage.

### Current-Controlled Analog Memory Operation

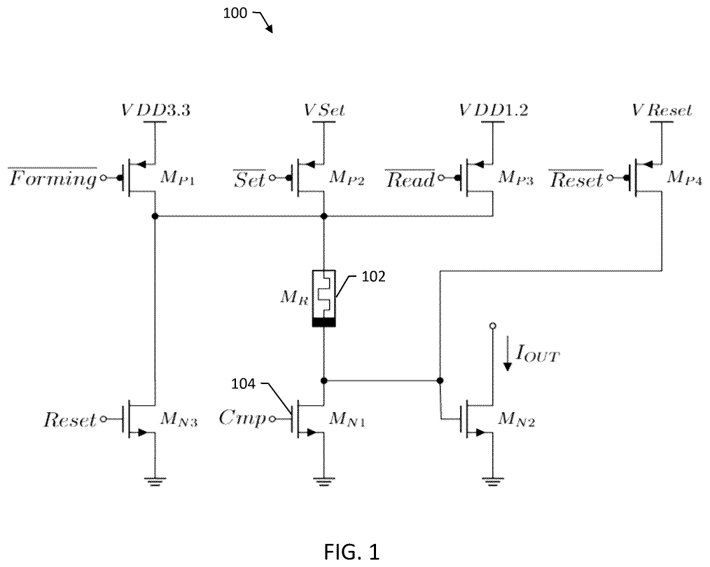

FIG. 1 illustrates an example analog memory circuit 100, comprising six transistors and one NVM element 102, in this case a two-terminal memristor (M_{R}). The six transistors includes a select transistor 104 (M_{N1}). An additional transistor (M_{N2}) is also included in the optional read out circuit that converts the first stage voltage output into a current signal, ready for use in current mode analog computing circuits. It should be noted that some of these transistors, specifically the forming transistor (M_{P1}), can be shared among several such memory cells, thus increasing the overall density of the analog memory circuit when many cells are integrated into a larger memory system. The select transistor (M_{N1}) is driven by an analog voltage signal Cmp at its gate, which is used to control the current through the NVM element M_{R}. Larger voltage values at Cmp are used to generate larger currents through the NVM element that force the device into a specific LRS resistance value. Once the analog value is stored as a resistance on M_{R}, it is read out using a smaller voltage value on Cmp, small enough that the current through M_{R} is too small to switch the resistance but large enough to generate a voltage between M_{R} and M_{N1} proportional to the analog value stored. During a read operation, the pull-up transistor M_{P3} is also turned on by the application of a high voltage for Read (Read being inverted to ground). The read out voltage between M_{R} and M_{N1} can drive the gate of the optional second stage transistor M_{N2}, which converts the read out signal into a current ready for use in analog computation.

A write operation comprises two steps: RESET the NVM element completely to the HRS resistance or “off state,” followed by a SET operation that more slowly switched the NVM resistance from HRS to a desired LRS resistance. For the RESET step, control signals Cmp, Set and Forming are all set to zero such that their corresponding transistors are turned off. During RESET, only the signal Reset is set to a high voltage (Reset being 0 V or ground). This turns on transistors M_{N3}, connected to the top of the NVM element M_{R}, and M_{P4}, connected to the bottom of M_{R}. Note that this reorients the NVM element such that the bottom is connected to a high voltage V_{Reset} whereas the top of the NVM element is connected to ground. In this way, the NVM element is reversed such that the negative voltage −V_{Reset} is applied across it, thus providing the full reset to HRS.

Once the NVM element is reset to HRS, the second phase of a write operation is a SET accomplished by driving control signal Set with a digital 1 (high voltage) and control signal Cmp with an analog voltage representing the analog value to be stored. When Set is high, Set is driven to ground thus turning transistor M_{P2} on. Likewise, Cmp turns transistor M_{N1} on, albeit not strongly on as Cmp is an analog voltage that controls the current through M_{N1} and thus M_{R} during the SET operation. All other transistors are turned off during a SET. The current through M_{N1} and M_{R} will determine the voltage drop across M_{R}, which reduces toward the threshold voltage of the NVM element as the resistance is reduced. Once the resistance of M_{R} is small enough, the voltage across the NVM element is also small enough that the device stops switching, having reached the desired analog LRS resistance value.

The final transistor shown is M_{P1}, whose gate is driven by the inverse of the signal Forming. As the name implies, this transistor is used for the one-time forming step, where a large current must be driven through the NVM element or memristor in order to initialize it by forming the first filament of the device. During forming, the signal Cmp is also large enough that M_{N1} is in the on state, providing the current path between VDD3.3 and ground during the forming operation. All other transistors will be turned off during forming. Once formed, the NVM element will be in a LRS state representative of the first formed resistance state. From this point onward, the NVM element can switch back and forth between HRS and LRS states with the application of voltages smaller than that required for forming. Forming occurs only once, to initialize the device, and this forming operation can be applied to multiple NVM elements simultaneously such that M_{P1} can be shared by multiple analog memory circuits.

### Example Showing Current-Control and Read Out

These example simulations are based on a hafnium oxide (HfO₂) memristor device, described in the literature, and fabricated by SUNY Polytechnic Institute. This particular HfO₂ device is defined by a minimum LRS of 3 kΩ and an absolute HRS in the range of 100 kΩ-150 kΩ. Experimental results for this device have shown a high degree of variability for resistance levels close to 100 kΩ and above. However, for lower resistance ranges, for example between 3 kΩ and 15 kΩ, variability is more tolerable. Thus, the example provided limits the range for analog resistance values to be between 3 kΩ and 15 kΩ.

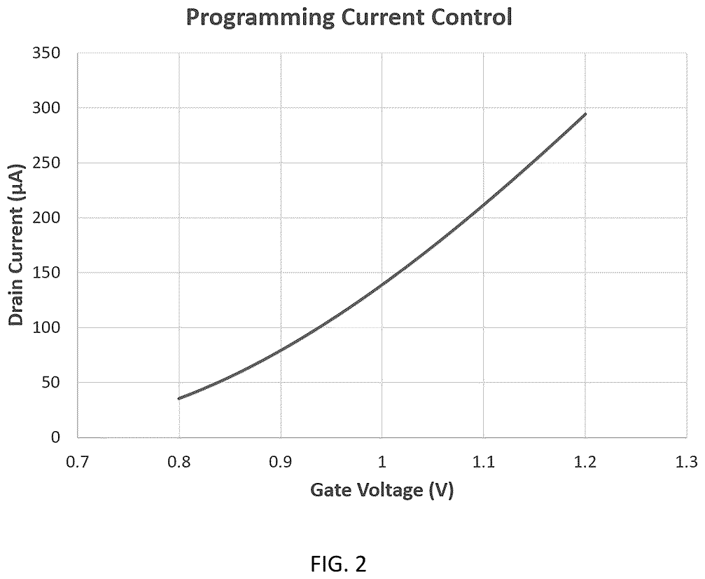

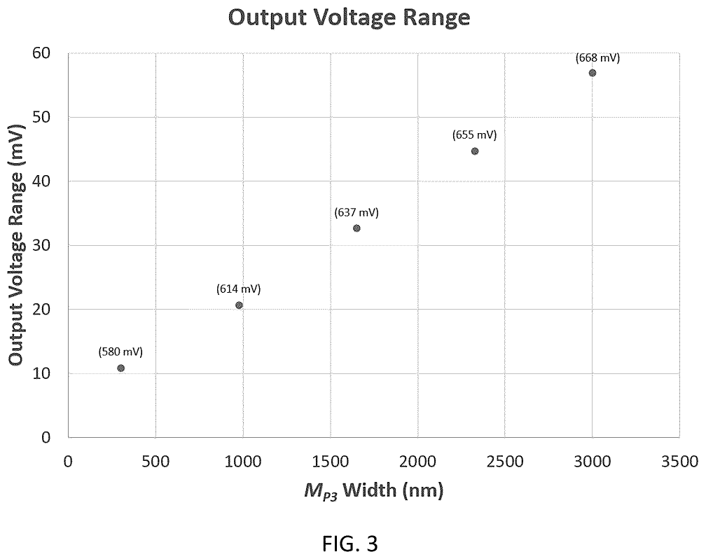

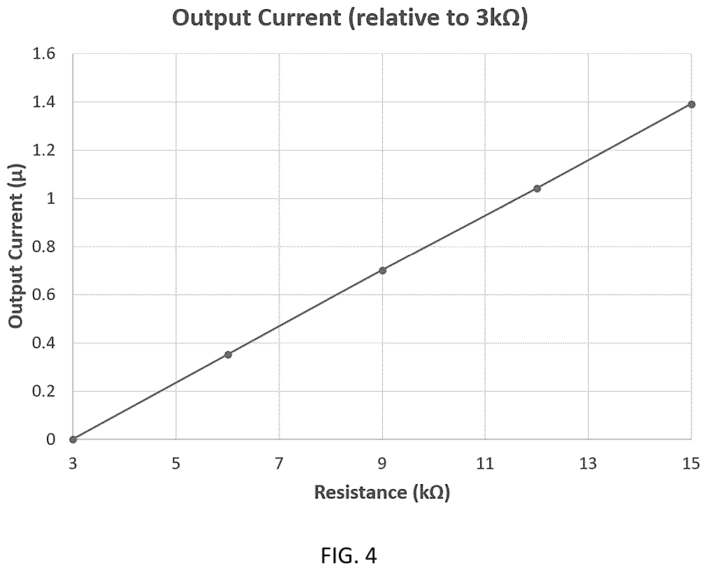

The current-controlled mechanism dictates how the NVM element switches into a specific value due to the maximum current allowed. The maximum allowed current is set by transistor M_{N1} in saturation. Reading the analog memory uses the same transistor for current control to produce a unique voltage for a specific resistance value. FIG. 2 illustrates the change in saturation current through the device for different voltages at Cmp during the resistance update. This example expects a voltage between 800 mV and 1.2 V used resulting in 50 μA to 300 μA through the NVM element. This current range should result in resistance values between 3 kΩ to 15 kΩ for the low resistance state of a hafnium oxide memristor. To detect the changes in resistance between the 3 kΩ to 15 kΩ range the Cmp voltage is set to a maximize the difference. The maximum range for different Cmp and M_{P3} are shown in FIG. 3 and the relative change in output current for different resistance values at a specific Cmp and M_{P3} are shown in FIG. 4. For increasing widths of transistor M_{P3} the maximum range and Cmp voltage increase. The Cmp voltage value is shown at each width. In this example the expected lowest resistance is 3 kΩ and the current output linearly increases as the resistance increases. This is due to the increase in voltage at the gate of Mₙ₂.

### STDP Based Online Learning for a Current-Controlled Memristive Synapse

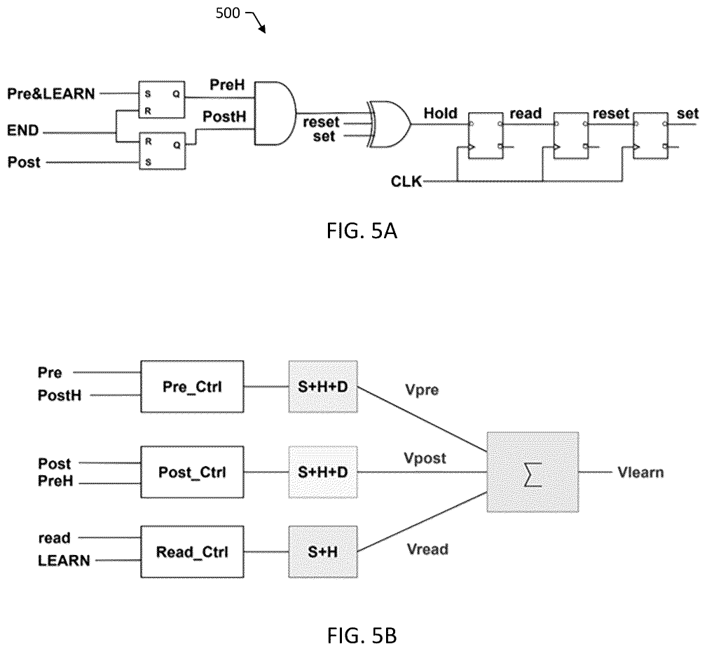

This document describes a circuit for an online learning memory update for analog memristors using a current-controlled programming mechanism. FIG. 5A is a block diagram of the STDP circuit 500.

The online learning technique is based on STDP, or spike-timing-dependent-plasticity. The circuit design is intended for non-volatile memory (NVM) devices, e.g. memristors, whose resistance is modified by applying a voltage or current beyond some given threshold. For example, the resistance of a hafnium oxide (HfO2) memristor will change when the voltage drop across the device exceeds a voltage threshold for some period of time. The switching properties of a memristor are based on a directional switching phenomena. When decreasing the resistance of the memristor, a positive voltage relative to the formation of the memristor is applied across the device, referred to as SET. When increasing the resistance, a negative voltage is applied, providing an operation called RESET. The SET operation reduces the resistance from the high resistance state (HRS) toward a near low resistance state (LRS) using transistors and voltages which apply a current limitation. Analogously, the RESET operation forces the memristor out of the near-LRS state and resets to the HRS with no transistor based current limitation. To manage memristor switching in the resistance (i.e. weight for neural circuits), this invention uses an analog voltage to manage the current limitation mechanism during the SET operation, thus providing desired incremental adjustments in resistance per the STDP learning rule.

In the context of brain-inspired or neural circuits, the memristor is used as a memory element that manages the connection strength, a part of the synapse, between two neurons. When an STDP learning event occurs, the neurons before, pre-neuron, and after, post-neuron, must activate to provide a potential weight update. The magnitude of the change in resistance, or weight update, is dependent on the timing of the pre-neuron and post-neuron activity. Increases in the synaptic strength occur when the pre-neuron activates before the post-neuron activation, a process called potentiation. A decrease in synaptic strength occurs when the post-neuron activates before corresponding pre-neuron activity, a process called depression. The magnitude of the resistance (or weight) change is greater when the activation events (e.g. spikes) occur closer together in time.

### STDP Based Online Learning Operation

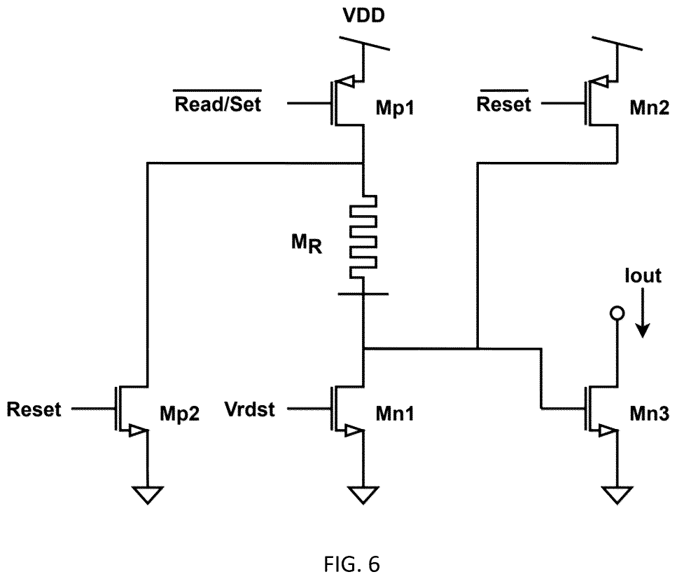

This system uses unidirectional switching for memristive resistance/weight updates, providing an overall reliable STDP mechanism. The SET operation can only further decrease the resistance value. Due to this, a three step operation is used for implementing the weight change. FIG. 5A shows the digital control circuit used to update the synaptic weight. The required steps for an STDP operation using this invention are: (1) the analog memory value (current or voltage representing resistance state) of the device is read and temporarily stored, (2) the device is fully reset to HRS using a RESET operation, and (3) the device is set into its new near LRS value using a current-controlled SET operation. The new value is generated by adjusting the previous voltage used for current control by the proportional time difference between the pre-neuron and post-neuron spikes. FIG. 5A illustrates the digital logic circuit to latch the learning process when both spikes occur. Once the process occurs the three operations, READ, RESET, and SET happen sequentially. The final value for managing the applied SET current limitation is controlled by a voltage generated by the time difference between the pre-neuron spike, the post-neuron spike and the current memristor value, the voltage Vrdst in FIG. 6. In FIG. 5B, the circuits used to generate the new voltage for controlling the applied current value are shown. The voltage output Vlearn is generated by combining information from the pre-synaptic neuron spike, post-synaptic neuron spike, and the synapse's present weight (stored as the NVM resistance in the analog memory circuit in FIG. 6). While there are three components to sum the current, only two are used at a time. The control circuits in FIG. 5B activate the correct circuits for potentiation or depression. For increasing the resistance of the memristor, the voltages Vpre and Vread are used. On the other hand, when decreasing the resistance, the voltages Vpost and Vread are used. The unused transistors are entirely in turn-off mode. This insures either potentiation or depression operations, but not both, occur on the synapse at any given time.

To generate the new resistance value for the memristor, a voltage for the gate of the memristor's current limiting transistor is needed. FIG. 6 shows the circuit used to implement the functions that update the memristor's resistance value. The SET operation uses transistors Mn1 and Mp1 to apply a high voltage across the device and reduce the memristor resistance. The RESET operation uses transistors Mp2 and Mn2 to apply a voltage with opposite polarity of the SET to increase resistance. The READ operation reuses the SET transistors Mn1 and Mp1 but at lower voltages to keep the memristor in its current state. The voltage Vlearn is used to generate Vrdst. This voltage takes information from the previous memristor state, represented by signal Vread, and combines it with spike timing information, represented by Vpre and Vpost.

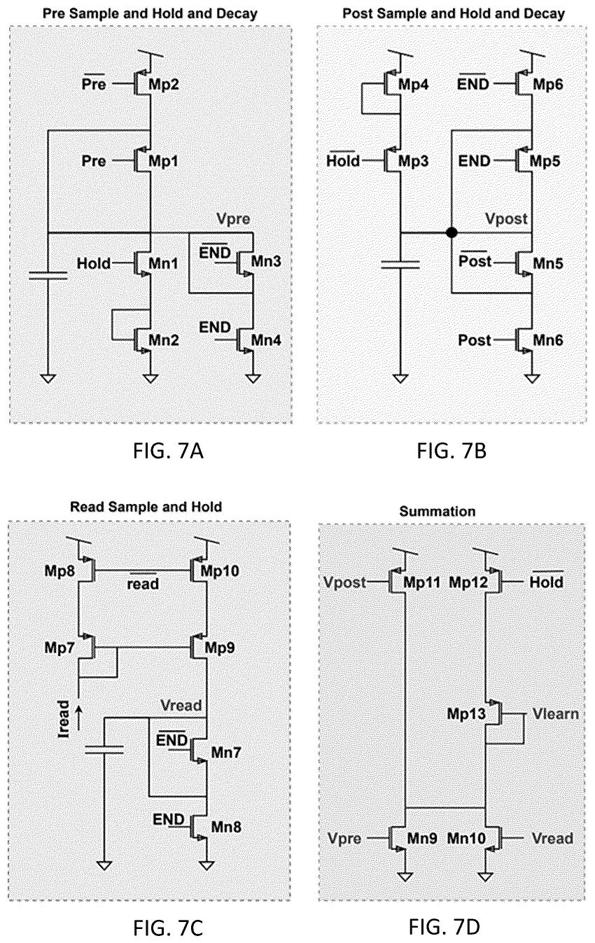

FIGS. 7A-7D illustrate potential transistor-level circuit implementations that can be used for each of the functional blocks in FIG. 5B. The spike timing information is captured by the voltages Vpre or Vpost. In FIG. 7A, the voltage Vpre is charged to 1.2 V when Pre is activated by the Pre control circuit in FIG. 5B. Vpre gradually reduces in voltage through Mn4 until the post-synaptic spike occurs. Once both spikes have occurred, the voltage Hold activates to stop the leakage of voltage at Vpre. After the learning process the voltage Vpre is reduced to 0 V by the activation of the voltage END and transistor Mn4. In FIG. 7B, the circuit for controlling Vpost follows the same control strategy except it is using Hold, END and Post. When activated, the voltage Vpost is reduced to 0 V and gradually increases through Mp4. When both spikes occur the voltage is held and after the update process the voltage is brought up to 1.2 V. In FIG. 7C, the current resistance of the memristor generates a specific value for Vread. This system is designed to regenerate the same current limitation used for the previous set operation. In FIG. 7D, Vlearn is generated by the summation of Vpost, Vpre, and Vread. For potentiation, Vpost is at 1.2 V and for depression Vpre is at 0 V which do not affect Vlearn. The voltage Vlearn is converted and applied to Vrdst in FIG. 1. The final SET operation in the learning process uses a new voltage value for current limitation to place the memristor in an updated low resistance state.

### Example Showing Current-Control for Memristor Update

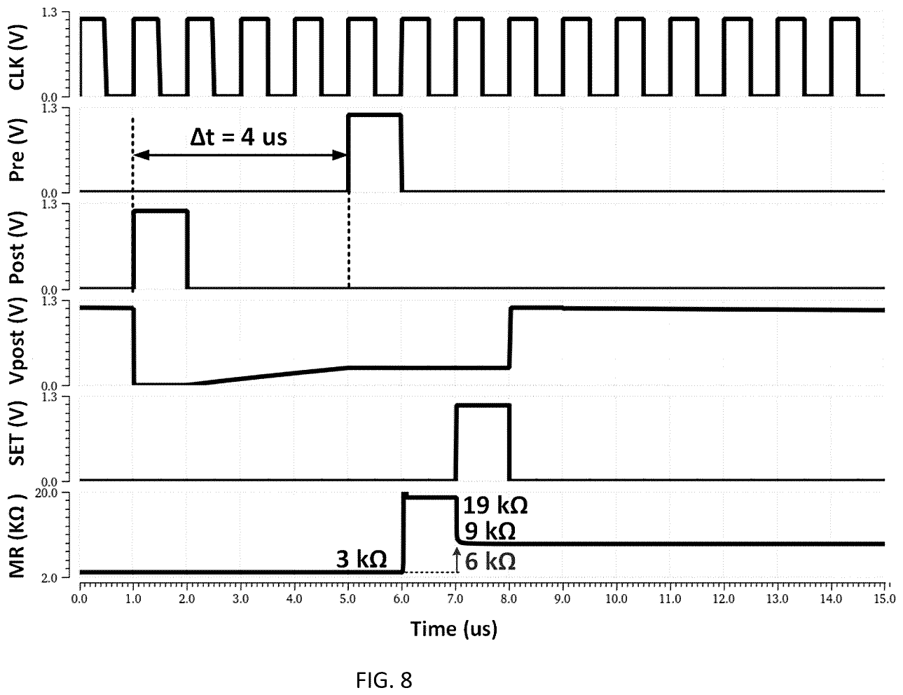

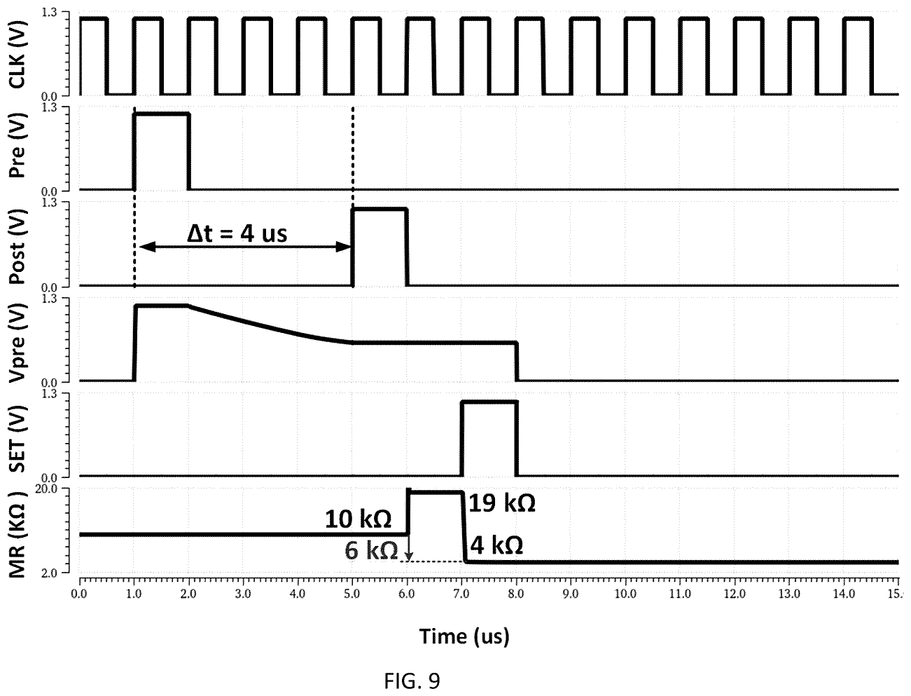

FIG. 8 shows the waveforms for decreasing the synaptic weight while FIG. 9 shows the waveforms for increasing the synaptic weight. The potentiation and depression processes use the same control signals but expect the opposite order of pre-synaptic and post-synaptic neuron spikes. The time between Pre and Post is 4 μs. When the pre-synaptic neuron fires, the voltage Vpre charges up and decays until the post-synaptic neuron fires. The voltage Vpost is held at 1.2 V and does not adjust the final resistance. The resistance of the memristor starts in a low resistance state, is reset into a high resistance state, and then set into a new low resistance state that is a lower resistance than the original. The magnitude of resistance change is related to the time between neuron spikes and captured by the decay of Vpre. For spikes occurring closer together the change in resistance will increase due to a higher voltage Vpre.

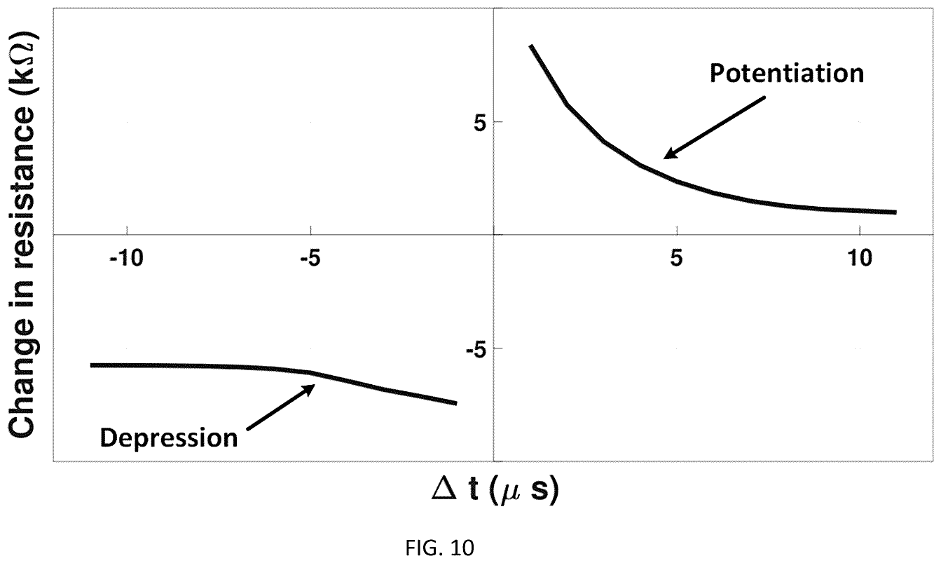

FIG. 10 shows the expected resistance change for different amounts of time between neuron spikes for a specific initial resistance. The time difference is the pre-synaptic spike's start time minus the post-synaptic spike's start time as seen in FIGS. 8 and 9. Positive time differences indicate potentiation and negative differences result in depression. The change in resistance is greatest the lower the time difference and gradually reduces. The change in resistance is taken as the final resistance minus the initial resistance. Using current limitation to update the low resistance state gives consistent positive and negative resistance changes relative to the spike timing.

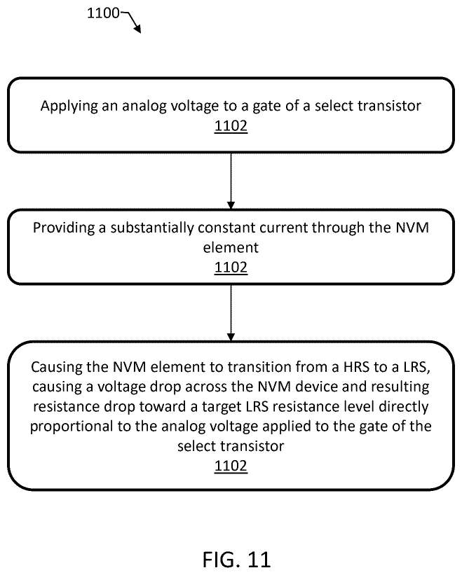

FIG. 11 is a flow diagram of an example method 1100 for controlling an analog memory cell using an NVM element. The method 1100 can be performed, e.g., by a memory control circuit using the analog memory cell of FIG. 1.

The method 1100 includes applying an analog voltage to a gate of a select transistor (1102). The method 1100 includes providing, by the select transistor, a substantially constant current through the NVM element (1104). The NVM can include at least one of: a metal-oxide memristor, a phase change memory (PCM) device, and a magnetic tunnel junction (MTJ) element.

The method 1100 includes causing the NVM element to transistor from a HRS to a LRS, causing a voltage drop across the NVM device and resulting resistance drop toward a target LRS resistance level directly proportional to the analog voltage applied to the gate of the select transistor (1106). The voltage drop across the NVM can be large enough to cause the NVM element to switch and cause the resistance drop based on the analog voltage applied to the gate of the select transistor.

In some examples, causing the NVM element to transition from a high resistance state (HRS) to a low resistance state (LRS) includes limiting a range for analog resistance values to be within a continuous device specific resistance range. In some examples, causing the NVM element to transition from a high resistance state (HRS) to a low resistance state (LRS) comprises limiting a range for analog resistance values to range from about 3 kΩ to about 15 kΩ or other appropriate range.

In some examples, the method 1100 includes reading the analog memory cell by providing a substantially constant current through the NVM element. Reading the analog memory cell can include providing a substantially constant current such that a voltage between the select transistor and the NVM element is based on a resistance of the NVM element. Reading the analog memory cell can include converting a first stage voltage output into a current signal.

Following long-standing patent law convention, the terms “a”, “an”, and “the” refer to “one or more” when used in this application, including the claims. Thus, for example, reference to “a component” includes a plurality of such components, and so forth.

Unless otherwise indicated, all numbers expressing quantities of ingredients, reaction conditions, and so forth used in the specification and claims are to be understood as being modified in all instances by the term “about”. Accordingly, unless indicated to the contrary, the numerical parameters set forth in this specification and attached claims are approximations that can vary depending upon the desired properties sought to be obtained by the presently disclosed subject matter.

As used herein, the term “about,” when referring to a value or to an amount of a composition, mass, weight, temperature, time, volume, concentration, percentage, etc., is meant to encompass variations of in some embodiments ±20%, in some embodiments ±10%, in some embodiments ±5%, in some embodiments ±1%, in some embodiments ±0.5%, and in some embodiments ±0.1% from the specified amount, as such variations are appropriate to perform the disclosed methods or employ the disclosed compositions.

As used herein, ranges can be expressed as from “about” one particular value, and/or to “about” another particular value. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the term “and/or” when used in the context of a listing of entities, refers to the entities being present singly or in combination. Thus, for example, the phrase “A, B, C, and/or D” includes A, B, C, and D individually, but also includes any and all combinations and subcombinations of A, B, C and D.

It will be understood that various details of the presently disclosed subject matter can be changed without departing from the scope of the presently disclosed subject matter. Furthermore, the foregoing description is for the purpose of illustration only, and not for the purpose of limitation.

The control systems and computer systems described herein may be implemented in hardware, software, firmware, or any combination thereof. In some exemplary implementations, the subject matter described herein may be implemented using a computer readable medium having stored thereon computer executable instructions that when executed by the processor of a computer control the computer to perform steps.

Exemplary computer readable media suitable for implementing the subject matter described herein include non-transitory computer readable media, such as disk memory devices, chip memory devices, programmable logic devices, and application specific integrated circuits. In addition, a computer readable medium that implements the subject matter described herein may be located on a single device or computing platform or may be distributed across multiple devices or computing platforms.

What is claimed is:

1. A method for controlling an analog memory cell using a non-volatile memory (NVM) element, the method comprising:
applying an analog voltage to a gate of a select transistor;
providing, by the select transistor, a substantially constant current through the NVM element; and
causing the NVM element to transition from a high resistance state (HRS) to a low resistance state (LRS), causing a voltage drop across the NVM device and resulting resistance drop toward a target LRS resistance level directly proportional to the analog voltage applied to the gate of the select transistor.

2. The method of claim 1 wherein the voltage drop across the NVM device is large enough to cause the NVM element to switch and cause the resistance drop based on the analog voltage applied to the gate of the select transistor.

3. The method of claim 1 comprising reading the analog memory cell by providing a substantially constant current through the NVM element.

4. The method of claim 3 wherein reading the analog memory cell comprises providing a substantially constant current such that a voltage between the select transistor and the NVM element is based on a resistance of the NVM element.

5. The method of claim 3 wherein reading the analog memory cell comprises converting a first stage voltage output into a current signal.

6. The method of claim 1 wherein the NVM element comprises at least one of: a metal-oxide memristor, a phase change memory (PCM) device, and a magnetic tunnel junction (MTJ) element.

7. The method of claim 1 wherein causing the NVM element to transition from a high resistance state (HRS) to a low resistance state (LRS) comprises limiting a range for analog resistance values to be within a continuous device specific resistance range.

8. The method of claim 1 wherein causing the NVM element to transition from a high resistance state (HRS) to a low resistance state (LRS) comprises limiting a range for analog resistance values to range from about 3 kΩ to about 15 kΩ.

9. A current-controlled analog memory circuit comprising:
a non-volatile memory (NVM) element; and
a select transistor coupled to the NVM element and configured to store an analog value as a resistance of the NVM element by providing a substantially constant current through the NVM element and causing the NVM element to transition from a high resistance state (HRS) to a low resistance state (LRS), causing a voltage drop across the NVM device and resulting resistance drop toward a target LRS resistance level directly proportional to an analog voltage applied to a gate of the select transistor.

10. The current-controlled analog memory circuit of claim 9 wherein the voltage drop across the NVM device is large enough to cause the NVM element to switch and cause the resistance drop based on the analog voltage applied to the gate of the select transistor.

11. The current-controlled analog memory circuit of claim 9 wherein the select transistor is configured for reading the analog memory circuit by providing a substantially constant current through the NVM element.

12. The current-controlled analog memory circuit of claim 11 wherein reading the analog memory circuit comprises providing a substantially constant current such that a voltage between the select transistor and the NVM element is based on a resistance of the NVM element.

13. The current-controlled analog memory circuit of claim 11 comprising an output converter circuit configured for converting a first stage voltage output into a current signal.

14. The current-controlled analog memory circuit of claim 11 wherein the NVM element comprises at least one of: a metal-oxide memristor, a phase change memory (PCM) device, and a magnetic tunnel junction (MTJ) element.

15. The current-controlled analog memory circuit of claim 9 wherein causing the NVM element to transition from a high resistance state (HRS) to a low resistance state (LRS) comprises limiting a range for analog resistance values to be within a continuous device specific resistance range.

16. The current-controlled analog memory circuit of claim 9 wherein causing the NVM element to transition from a high resistance state (HRS) to a low resistance state (LRS) comprises limiting a range for analog resistance values to range from about 3 kΩ to about 15 kΩ.

17. A system for spike-timing-dependent plasticity (STDP) online learning, the system comprising:
a current-controlled memristive synapse; and
an STDP online learning circuit configured for limiting a range of operation of the current-controlled memristive synapse to resistance states near the low resistance state (LRS) of the current-controlled memristive synapse.
